(19) United States
(12) Patent Application Publication
(10) Pub. No.: US 2022/0336234 A1
(43) Pub. Date: Oct. 20, 2022

(54) METHOD OF FABRICATING A LATTICE STRUCTURE

(71) Applicants: Microsoft Technology Licensing, LLC, Redmond, WA (US); Paul Scherrer Institute (PSI), Villigen PSI (CH)

(72) Inventors: Peter KROGSTRUP JEPPESEN, Copenhagen (DK); Mohana Krishnappa RAJPALKE, Lyngby (DK); Niels Bernhard SCHRÖTER, Brugg (CH); Nicolò D'ANNA, Baden (CH); Gabriel AEPPLI, Windisch (CH); Nicolas Pierre Michel BACHELLIER, Würenlingen (CH)

(73) Assignee: Microsoft Technology Licensing, LLC, Redmond, WA (US)

(21) Appl. No.: 17/753,820

(22) PCT Filed: Sep. 16, 2019
(86) PCT No.: PCT/EP2019/074704

§ 371 Date: Mar. 15, 2022

(51) Int. Cl. H01L 21/62; H01L 49/00; H03K 17/56

(52) U.S. Cl. CPC H01L 21/62; H01L 49/006; H03K 17/56

(57) ABSTRACT

According to a first aspect of the disclosure, there is provided a device comprising: a substrate comprising a III-V semiconductor having a crystalline surface; and a kagome lattice formed from atoms of an element with atomic number Z greater than or equal to 14, deposited on said surface of the semiconductor. According to a second aspect there is provided a fabrication method for forming a kagome lattice or other lattice structure such as a honeycomb or Moiré super lattice.

### BACKGROUND

As shown in FIG. 1A, a kagome lattice consists of a lattice of vertices 12 and edges 14 arranged in a trihexagonal tiling. Interest has been expressed in forming a 2D atomic kagome lattice, because of the useful electronic properties such a structure would have for applications such as spintronics or quantum computing. This would comprise a kagome lattice formed from a network of atoms arranged in a lattice structure, in which case each vertex would correspond to the nucleus of an atom, and the edges would correspond to the direction of maximum electron density between atoms. In other words the edges are the lines along which electrons can travel. The edges could also be thought of as the bonds between the atoms.

Zhi Li et al (“Realization of flat band with possible nontrivial topology in electronic Kagome lattice”, Science Advances 16 Nov. 2018, Vol. 4, no. 11, eaau4511, DOI: 10.1126/sciadv.aau4511) has disclosed a quasi-2D kagome lattice formed from two twisted silicon layers on silver. However, here the silicon atoms do not form a Kagome lattice, but rather the Moiré pattern of the two layers form a kagome lattice arrangement. No two-dimensional atomic structure forming a kagome lattice on any substrate has yet been reported to date, as far as the authors of the present disclosure are aware.

### SUMMARY

The inventors have determined that atoms of heavy elements are capable of forming a kagome lattice on the surface of a III-V semiconductor. Heavy atoms have a strong spin-orbit coupling, making them particularly useful in this lattice arrangement for a number of applications such as protected Majorana bound states (MBS), and other quantum computing and spintronics applications.

Hence according to one aspect disclosed herein, there is provided a device comprising: a substrate comprising a III-V semiconductor having a crystalline surface; and a kagome lattice formed from atoms of an element with atomic number Z greater than or equal to 14, deposited on said surface of the semiconductor.

The inventors have observed for the first time that atoms of lead (Pb) are capable of forming a kagome lattice. It is also believed that this will work for other heavy elements on similar semiconductor substrates.

Kagome lattices formed from heavy atoms will exhibit exotic electronic phases which have a number of technological applications, examples of which will be set out in more detail in the Detailed Description.

The inventors have also provided a fabrication procedure for forming kagome lattices and other lattice structures such as honeycombs and Moiré superlattices, from Pb or other heavy elements, on the surface of semiconductor substrates such as InAs.

That is, according to another aspect disclosed herein, there is provided a method of depositing an element onto a substrate so as to form a lattice structure, the method comprising: providing a substrate comprising at least a layer of a III-V semiconductor; treating the substrate to provide a cleaned, exposed surface of the semiconductor having a crystalline structure terminated at said surface; depositing a layer of the element on said surface, wherein the element has an atomic number Z greater than or equal to 14; annealing the heavy element following said deposition so as to increase mobility of the element on said surface, wherein the heavy element interacts with the crystalline structure at the surface of the semiconductor during at least a period of said increased mobility in order to form said lattice structure.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Nor is the claimed subject matter limited to implementations that solve any or all of the disadvantages noted herein.

### BRIEF DESCRIPTION OF THE DRAWINGS

To assist understanding of embodiments of the present disclosure and to show how such embodiments may be put into effect, reference is made, by way of example only, to the accompanying drawings in which:

FIG. 1A shows the geometry of a kagome lattice,

FIG. 1B schematically illustrates the concept of valence and conduction bands,

FIG. 1C schematically illustrates the band structure of a Kagome lattice, including Dirac cones and a flat band,

FIG. 2A is a STM image of the semiconductor substrate after decapping of an amorphous passivation layer,

FIG. 2B shows a height profile of two lines through the image of FIG. 2A,

FIG. 2C shows a zoomed-in region of the image of FIG. 2A,

FIG. 3A is a STM image of a kagome lattice formed from Pb atoms,

FIG. 3B shows a zoomed-out version of the image of FIG. 3A,

FIG. 3C shows an intermediate level of zoom between FIGS. 3A and 3B,

FIG. 3D shows STS measurements from a point in the lattice of FIGS. 3A-C,

FIG. 4 is a flow chart illustrating an example fabrication method, and

FIGS. 5A-E are images of some further lattice structures.

### DETAILED DESCRIPTION OF EMBODIMENTS

As mentioned, kagome lattices formed from heavy atoms exhibit exotic electronic phases which have a number of technological applications.

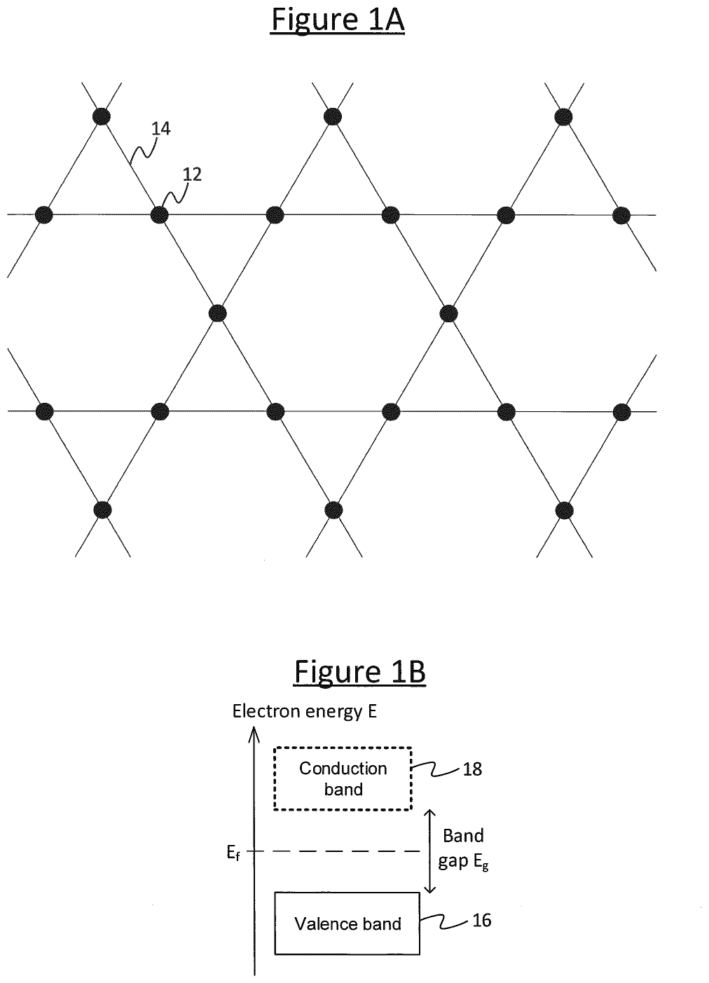

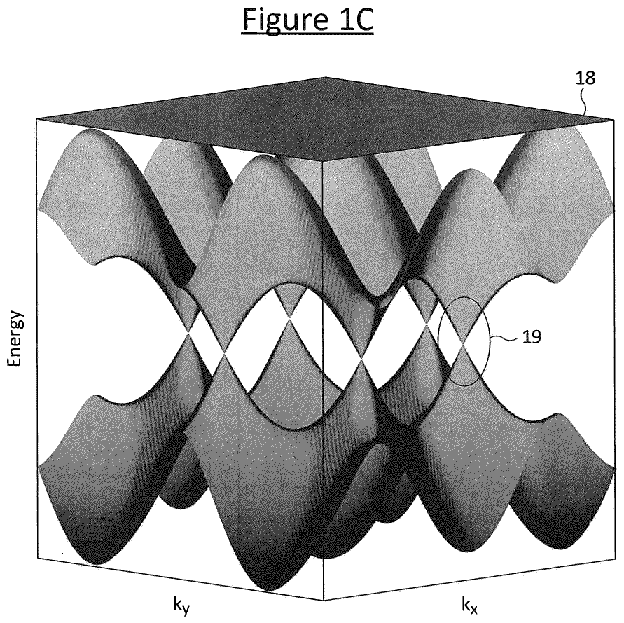

In solid state physics, the concept of the valence and conduction bands are well known. These are illustrated schematically in FIG. 1B. The valence band 16 is highest range of electron energies E in which electrons exist in a bound state at absolute zero. The conduction band 18 on the other hand corresponds to higher energy states where electrons are unbound and can move freely within the crystal lattice, enabling them to act as charge carriers and thereby participate in conduction of electric current. In a conductor the valence and conduction bands overlap, enabling electrons to move freely into the conduction band. In an insulator or semiconductor there is a band gap E_{g} between the valence band of the material and the conduction band. This is a range of energy E in which no electron can exist due to the quantization of energy states. It is the minimum amount of energy required to release an electron from a bound state in the valence band into the conduction band. In a semiconductor the band gap is small and so some electrons can become excited from the valence band to the conduction band by thermal excitation at room temperature. The Fermi level E_{f} is the amount of thermodynamic work required to add one electron to the body.

A solid has not just a band gap but rather a band structure. I.e. the energy of the valence and conduction electrons vary as a function of coordinates in reciprocal space kₓ, k_{y} (the spatial frequency domain). Any generic Kagome lattice is expected to show both flat bands and Dirac cones in its electronic band structure. Heavy atoms have large spin-orbit coupling that will open large gaps in the Dirac cones and between the flat band and Dirac bands. FIG. 1C is a schematic sketch of an example band structure exhibiting Dirac cones 19 and a flat band 18, as a function of kₓ and k_{y} (angular spatial frequency in the x and y directions respectively).

The position of the Fermi level E_{f} determines the topological phase. For instance, if the Fermi level is inside the gap of the Dirac cone or between Dirac cone bands and flat band, then a 2-dimensional topological insulator with spin-polarized edge states is formed. However, if the Fermi level is tuned into the flat band, then strongly correlated phases can be obtained.

In the former case, this gapped phase is a 2-dimensional topological insulator (see Guo et al., PRB 80(11), 113102) with spin-polarized edge states that can be used for technological applications. E.g. such application include spintronic applications (Noel et al., PRL 120.16 (2018): 167201) and Majorana based quantum information applications (Alicea, Rep. Prog. Phys. 75 076501; Heart et al., Nat. Phys. 10, 638-643 (2014); Yang et al., arXiv:1904.02677v1).

In the case of flat bands on the other hand, the flat bands are expected to show strongly correlated phases that are relevant for technological applications, such as:
high temperature fractional quantum Hall states (Tang et al., PRL 106.23 (2011): 236802), that can be used for quantum computation (Nayak, Rev. Mod. Phys. 80.3 (2008): 1083);
unconventional superconductivity that may lead to high temperature superconductivity (Cao et al., Nature 556, 43-50);
emergent ferromagnetism that may realize a quantum anomalous Hall phase (Sharpe et al., Science 365, 605-608 (2019)), which is also relevant for Majorana based quantum computation (Lian et al., Proc. Natl. Acad. Sci. 115.43 (2018): 10938-10942).

For instance, topological quantum computing (TQC) relies on the creation of topological protected bound states. There are several material candidates, one promising class of new materials are 2D Kagome lattices, however, the lattice needs to consist of heavy atoms which is needed to get a strong spin orbit coupling, a prerequisite for a strong topological gap.

Majorana bound states (MBS) are topologically protected fractional electronic states that have huge potential as a basic for fault tolerant quantum computation (Nayak et al., Rev. Mod. Phys. 80.3 (2008): 1083; S. D. Sarma, npj Quantum Information 1 (2015): 15001; Lian et al., Proc. Natl. Acad. Sci. 115.43 (2018): 10938-10942).As will be evidenced herein, the inventors have discovered that Pb forms a kagome lattice on InAs. The inventors also believe that this will also work with other heavy elements on similar semiconductor substrates. Heavy elements will experience a spin-orbit induced gap. An analogy may be drawn with known honeycomb lattices made up from heavy elements, which also form gapped Dirac cones that are 2D topological insulators. For instance, a honeycomb lattice of silicon is predicted to have a gap of 1.55 meV (“Quantum Spin Hall Effect in Silicene and Two-Dimensional Germanium”, Cheng-Cheng Liu et al, Phys. Rev. Lett. 107, 076802, published 9 Aug. 2011). Honeycomb lattices of germanium or tin are predicted to have gaps of ^{˜}24 meV and ^{˜}100 meV, respectively (“Large-Gap Quantum Spin Hall Insulators in Tin Films”, Yong Xu et al, Phys. Rev. Lett. 111, 136804, published 24 Sep. 2013). The size of the gap effectively determines the temperature at which any topological device could operate. Since a gap of E=1.55 meV would correspond to a theormodynamic temperature of T==18K, which can easily be reached in a dilution fridge, this comparison would suggest that elements heavier than silicon (Z=14) may be suitable. More preferably however, the atomic number Z may be greater than or equal to 32 (Germanium), with T=279 K.

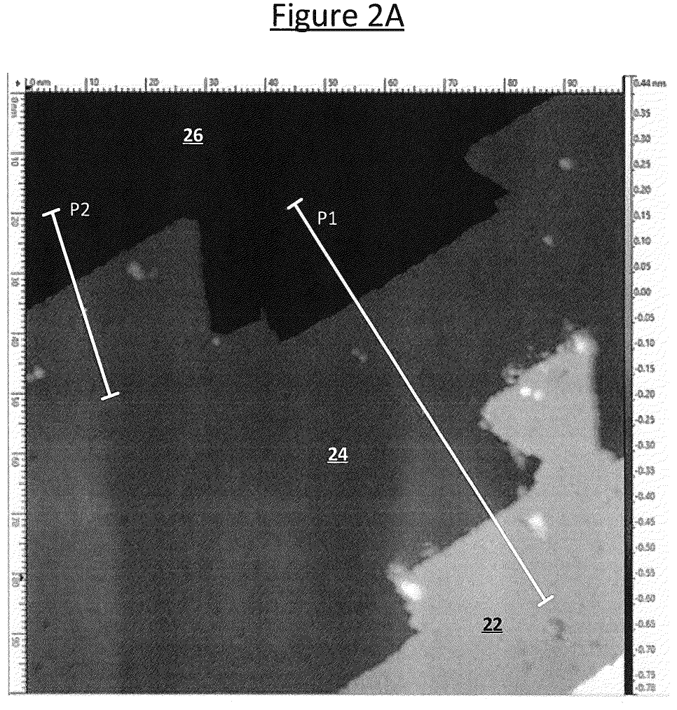

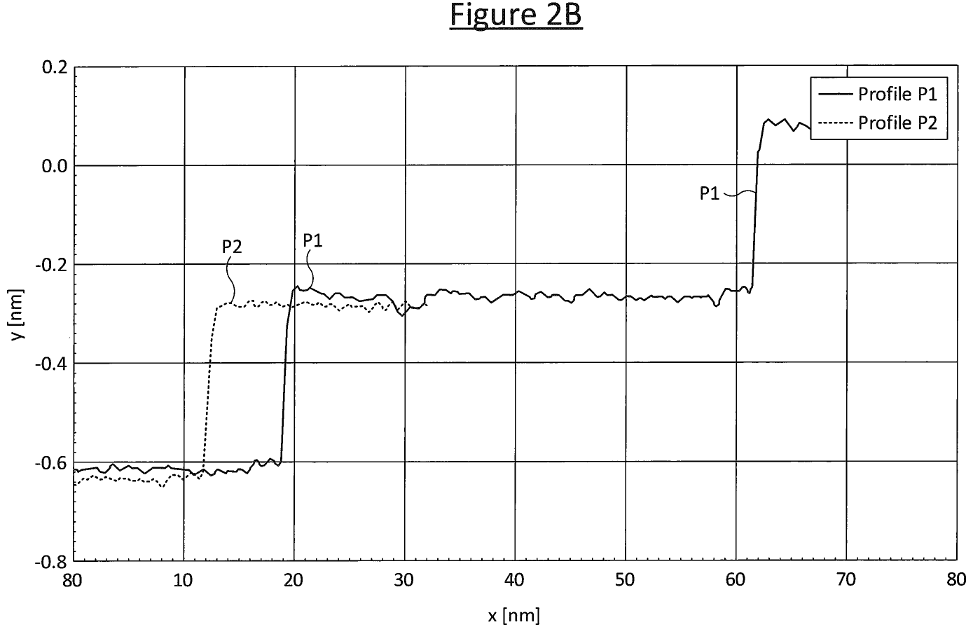

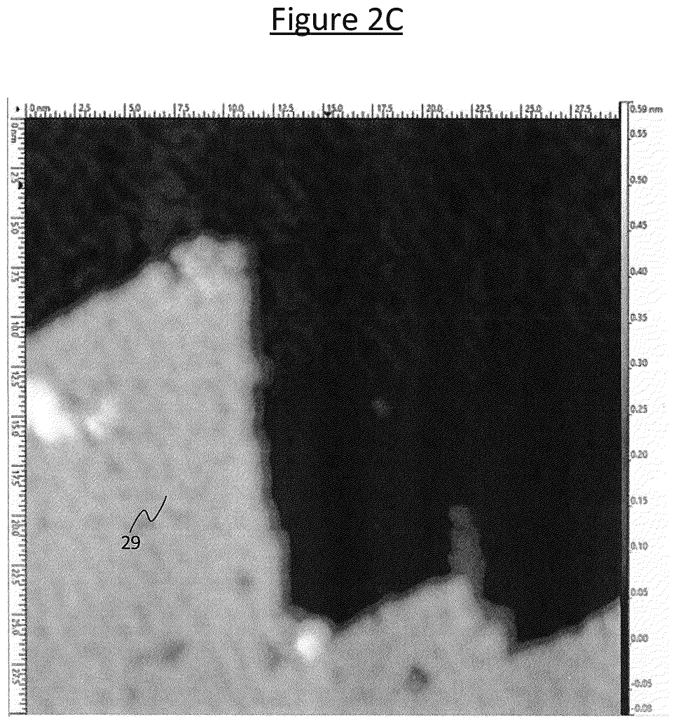

FIG. 2A is a scanning tunnelling microscopy (STM) image taken by the inventors, showing the semiconductor substrate after removal of the amorphous passivation layer by annealing. Regions 22, 24, and 26 show the terraces of the semiconductor substrate. FIG. 2B shows a height profile showing the low roughness of the substrate after annealing. FIG. 2C shows a zoomed-in region of the image of FIG. 2A.

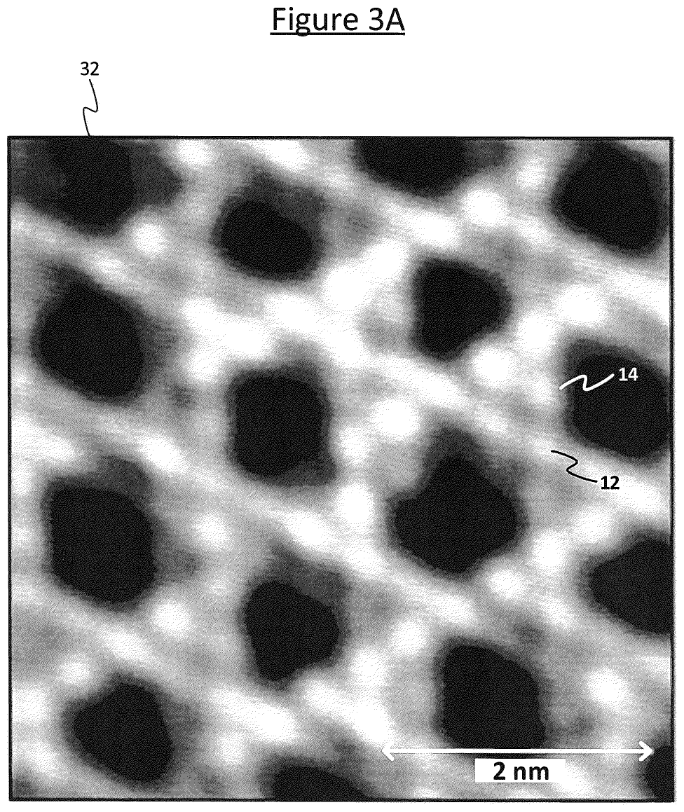

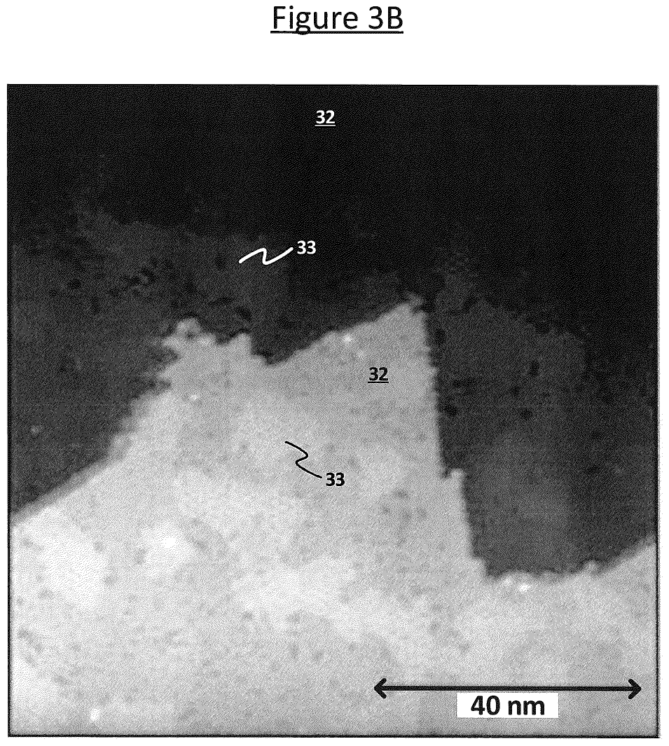

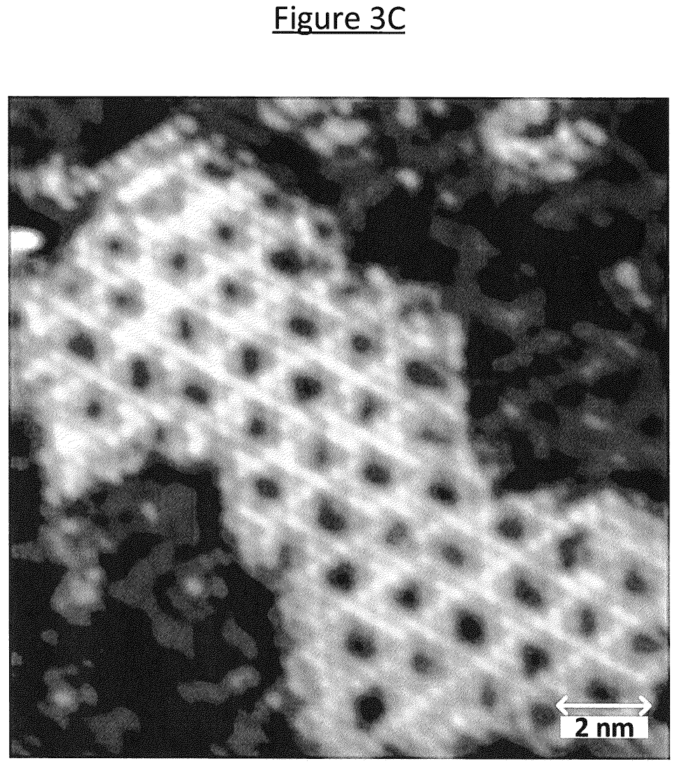

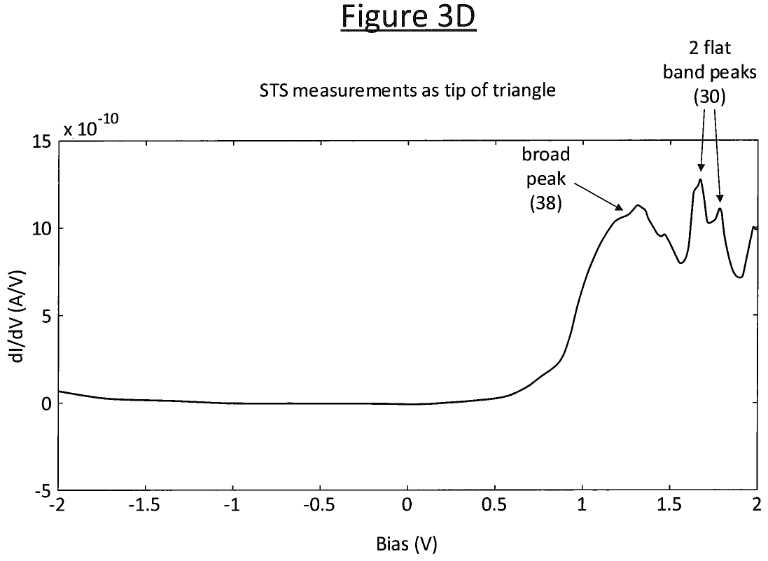

FIG. 3A is a scanning tunnelling microscopy (STM) image taken by the inventors, showing a kagome lattice formed from lead (Pb) atoms on the surface 32 of a substrate. This is the first time that lead has been seen to form a kagome lattice. Each vertex 12 of the kagome lattice is formed from a respective Pb atom, and the edges 14 between the vertices are the lines of maximum electron density between the Pb atoms at the vertices of the kagome lattice. The bright spots in FIG. 3A are the Pb nuclei. In some cases the inventors have observed that additional Pb atoms may also be formed along some of the edges 14. This may be referred to herein as a “decorated” kagome lattice. E.g. in the example of FIG. 3A, each edge 14 has one of the extra “decoration” Pb atoms in the middle of the edge.

In the example illustrated, the upper surface 32, upon which the kagome lattice is formed, consists of indium arsenide (InAs). However, other III-V semiconductors could also be used, such as gallium arsenide (GaAs) or indium antinomide (InSb) or gallium antinomide (GaSb) or indium phosphate (InP). More generally still, in principle any crystalline surface could be used, preferably one exhibiting hexagonal, triagonal or tri-hexagonal motifs as this will promote the formation of the Pb atoms into the kagome lattice structure as they move over the surface and interact with the underlying crystal structure during the formation of the lattice.

For instance the unreconstructed surface of InAs(111)B is triagonal. An unreconstructed surface is a surface obtained by simply truncating the bulk crystal structure. However, many surfaces minimize their energy by rearranging their atoms such that they form a lattice with new periodicity (a reconstruction). However, that does not seem to be the case for InAs(111)B. This is sufficient to facilitate the formation of a tri-hexagonal kagome lattice thereover. Other surfaces, such as InAs(111)A, do reconstruct and form tri-hexagonal lattices, which could also be suitable for fabrication of a kagome lattice.

Preferably the surface 32 should also be substantially flat, and cleaned so as to be substantially devoid of any oxides. Note also that the term “upper” or such like, as used herein, does not mean with respect to gravity, but rather refers to the side of the substrate being worked, i.e. the side upon which the kagome lattice is formed.

In the example shown, the surface 32 was formed from the InAs (111) B face of the indium arsenide substrate. However, it could also be formed from the (111) B face of any III-V semiconductor such as GaAs, InP, InSb or GaSb or even the (111) A face, as these also exhibit the same triagonal or trihexagonal motifs. E.g. as mentioned, for InAs111-A, it is known that a surface reconstruction leads to a trihexagonal reconstruction. As will be familiar to a person skilled in the art, a III-V A semiconductor refers to a sample terminated with the group HI element at its surface, and a III-V B semiconductor refers to a sample terminated with the group V element at its surface. E.g. so InAs A is indium terminated, and InAs B is arsenic terminated. The notation (111) refers to a particular plane through the crystal structure, denoted in reciprocal space.

Reciprocal space is a spatial frequency domain transform of a representation of a periodic crystal structure R=n₁a₁+n₂a₂+n₃a₃ in the spatial domain (e.g. Cartesian space in this example), where a₁, a₂, a₃ are vectors each representing the direction of a recurring pattern of atoms or molecules, and n₁, n₂ n₃ are scalars representing the space between instances of the pattern along each respective direction. In reciprocal space the same lattice can be described by a set of vectors each of the form (Imn), the set being a spatial frequency domain transform (e.g. Fourier transform) of the spatial domain representation R. Each vector (Imn) represents the normal to a recurring plane of atoms or molecules in the lattice structure, and the magnitude of the vector represents the relative spacing between instances of the plane. So (111) in reciprocal space means the crystal has a recurring set of planes with a normal in direction (111) in Cartesian space. Reference to a (111) face refers to an instance of that recurring plane that terminates at the surface 32.

Preferably the substrate, or at least an upper portion of it terminating with the surface 32, is formed from a semiconductor. This means the device can be gated in order to tune the Fermi level of the atomic band structure, in order to tune between different topological phases. Preferably the semiconductor is a semiconductor with a well-defined band gap such as InAs, GaAs, or InP which is semi-insulating.

FIG. 3B shows a zoomed out area containing the region of Pb lattice shown in FIG. 3A. FIG. 3C shows a region of the Pb kagome lattice at an intermediate level of zoom between FIGS. 3A and 3C. The grey and dark areas are different terraces of the semiconductor. The Pb kagome lattice has a different structure than the substrate and forms small islands 33, and outside of the islands only the substrate 32 is visible.

FIG. 3D shows a plot of scanning tunnelling spectroscopy (STS) measurements taken from the tip of the triangle in a lattice. The horizontal axis shows the bias voltage (V) applied between the sample and the tip of the STM probe, and the vertical axis shows the rate of change of current (I) tunneling between the STM tip and the sample with respect to V. As can be seen, a broad peak 38 is observed around a bias of 1 to 1.5 V. The STS curve also shows two sharp peaks indicating flat bands with large local DOS (density of states)

As mentioned, in the example shown the inventors observed a “decorated” kagome lattice with additional atoms on the sides of the triangle. This may result in a second flat band peak. In the decorated kagome lattice, an additional Pb atom may sit at the centre of every edge 14 in the kagome lattice. Alternatively, ferromagnetism may split a spin-degenerate flat band into two spin polarised flat bands.

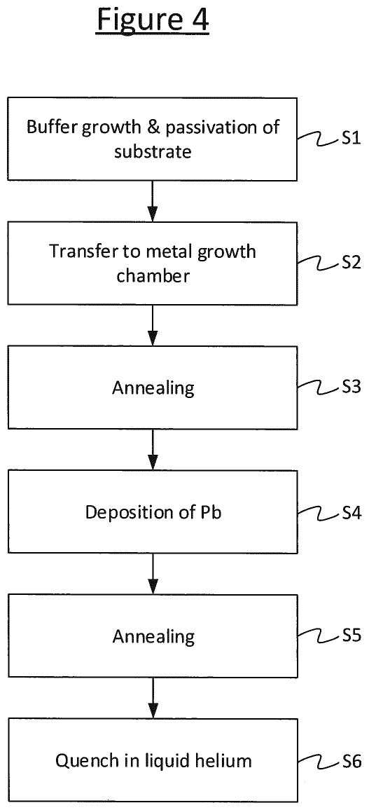

FIG. 4 gives a flowchart of the method used by the inventors to fabricate the Pb kagome lattice shown in FIGS. 3A to C. The method begins at step S1 with a step of providing the semiconductor substrate (in this case InAs). Buffer growth refers to a process of starting with an initial layer of the semiconductor, then heating to get rid of oxides, then growing a further layer of the semiconductor. Oxides create some roughness on the surface of the substrate, and in order to enable the Pb atoms to move more freely over the surface 32 of the substrate in subsequent steps, it is preferable to make the surface 32 as smooth as possible. In embodiments, step S1 also comprises passivation of the substrate with a layer of amorphous group V element following the buffer growth. The purpose of the passivation layer is to avoid oxidation of the semiconductor surface during the transfer to the metal growth chamber (see below), which happens outside of the vacuum. Before the growth of the Pb kagome lattice, the passivation layer will be removed by annealing.

By way of example, in embodiments step S1 comprises buffer growth of InAs (111) B and passivation with 5 to 10 nm of amorphous As in a molecular beam epitaxy (MBE) chamber.

More generally however, step S1 could comprise starting with any crystalline substrate, preferably exhibiting hexagonal, trigonal or tri-hexagonal motifs in the upper surface 32. The substrate could be formed using any suitable known fabrication technique, and the surface 32 could be prepared by any suitable treatment, e.g. by cleaving or cleaning with a chemical cleaning step instead of or in addition to the buffer growth and/or passivation.

At step S2 the substrate is transferred to a metal growth chamber. In embodiments it is transferred in air. However, this is not essential. In other embodiments it could be transferred in vacuum via a vacuum tunnel between the substrate growth chamber and the metal growth chamber. As another alternative, no transfer between chambers is needed at all, and instead the substrate and the Pb will be grown in the same, integrated chamber. This would obviate the purpose of the passivation of step S1. This is in fact more preferable, though integrated chambers capable of both types of growth tend to be more expensive.

At step S3 the substrate undergoes annealing to remove the passivated layer of amorphous group V element. In embodiments step S3 comprises annealing of the passivated InAs (111) B at 375° C. for 60 minutes (i.e. the sample is heated to that temperature and then allowed to cool). The sample surface 32 then shows an atomically flat surface as shown in FIGS. 2A to C.

More generally, step S3 could be replaced with any cleaning or preparation step, for example one could use cleaving or a chemical treatment instead of annealing. This could be in addition to, or an alternative to, any preparation or treatment performed in step S1. Also, where annealing is used, the process is not sensitive to the exact temperature used. For example in other embodiments the annealing may be performed to any temperature up to 400° C. or even higher temperatures, depending on the substrate that is used.

If step S2 is performed in a vacuum, or the substrate and Pb are both formed in the same chamber, then annealing or other cleaning step at S3 is not necessarily required at all since the surface 32 of the substrate would never have been exposed to air. However, as mentioned, integrated chambers are more expensive, so for practical purposes steps S2 and S3 may be required.

At step S4 the Pb is deposited onto the surface 32 of the substrate within the metal growth chamber (or integrated chamber). In embodiments this step comprises deposition of Pb from an e-beam evaporator with deposition rate ^{˜}1 nm/min with substrate temperature T=80K. However these exact parameters are not essential. Furthermore, deposition methods other than electron beam evaporation can be used. For example, an alternative would be to use a Knudsen cell, which is a form of resistive heater. An e-beam evaporator is preferred as it gives the cleanest deposition, but this is also the most expensive option and not essential.

At step S5 the combination of the substrate and Pb are annealed up to room temperature. E.g. after deposition of the Pb at T=80K, the substrate and sample are heated (annealed) to room temperature T=300K. In embodiments this may be repeated over multiple annealing cycles. The purpose of this step is to increase the mobility of the Pb atoms on the surface 32. When the Pb is heated it becomes more mobile over the surface 32, and then as it cools it self-assembles into the kagome lattice. This is also promoted by the Pb atoms interacting with the underlying crystal structure of the substrate. It is believed that the underlying hexagonal, trigonal or tri-hexagonal substrate forces the Pb to also assemble in a hexagonal structure. For instance InAs111-A exhibits a trihexagonal surface.

Step S6 is not part of the fabrication process for the device per se. Its purpose is to allow for the characterisation of the fabricated device, i.e. to take measurements with a scanning tunnelling microscope (STM). The temperature at which the device would be operated in actual use would depend on the application, but would likely be below 10° K. Therefore whether being measured for test purposes or used in an actual end application, in most cases there would likely be a cooling step of some kind, but this does not necessarily have to be done in liquid helium. E.g. as an alternative, the cooling could be done in a dry fridge. Also, in the case of taking measurements, techniques other than STM are also possible, e.g. atomic force microscopy (AFM), transmission electron microscopy (TEM), surface X-ray diffraction and electrical characterizations in the presence or absence of optical, magnetic and applied voltages.

In the illustrated example the lattice is verified with an STM scan as shown in FIGS. 3A to C.

The Pb atoms have a large spin-orbit coupling that will open large gaps in the dirac cones and between the flat band and Dirac bands. This gapped phase is a two-dimensional topological insulator with spin-polarised edge states that can be used for a variety of technological applications such as TQC, spintronics, or high temperature superconductivity.

The disclosed fabrication method can also be used to form a kagome lattice from other heavy elements, such as mercury (Hg) or bismuth (Bi). Furthermore, besides the kagome lattice structure, the disclosed fabrication techniques can also be used to fabricate other lattices from such heavy elements. Heavy for the present purposes may be defined as Z greater than or equal to 32 (Germanium). In embodiments the heavy element may have an atomic number Z greater than or equal to that of lead (82).

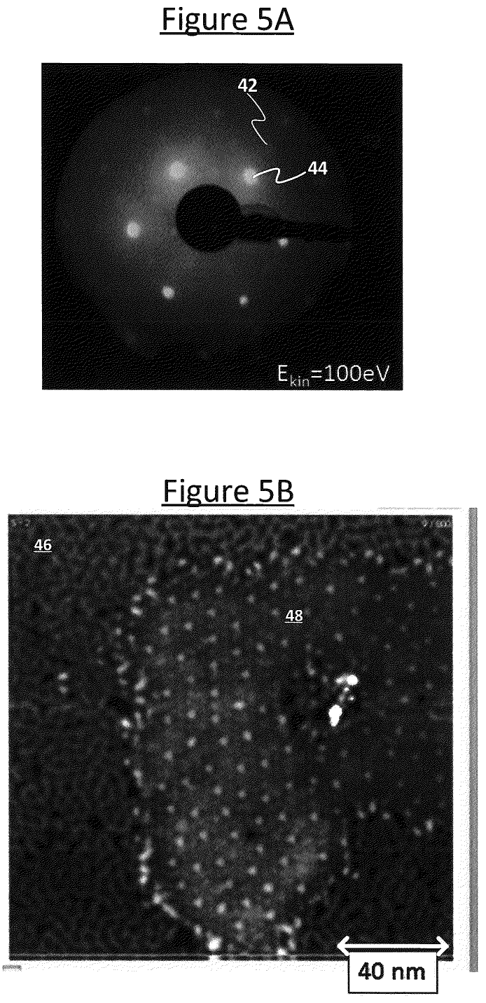

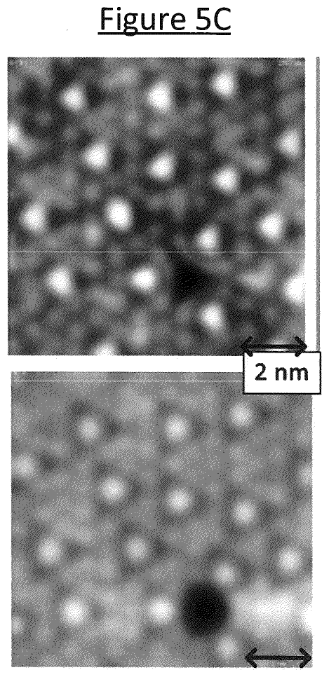

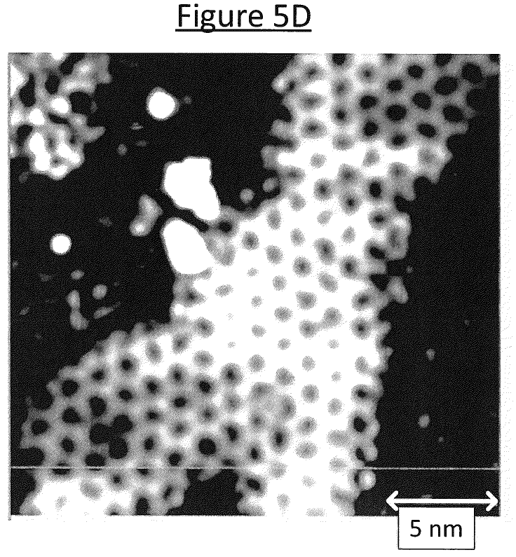

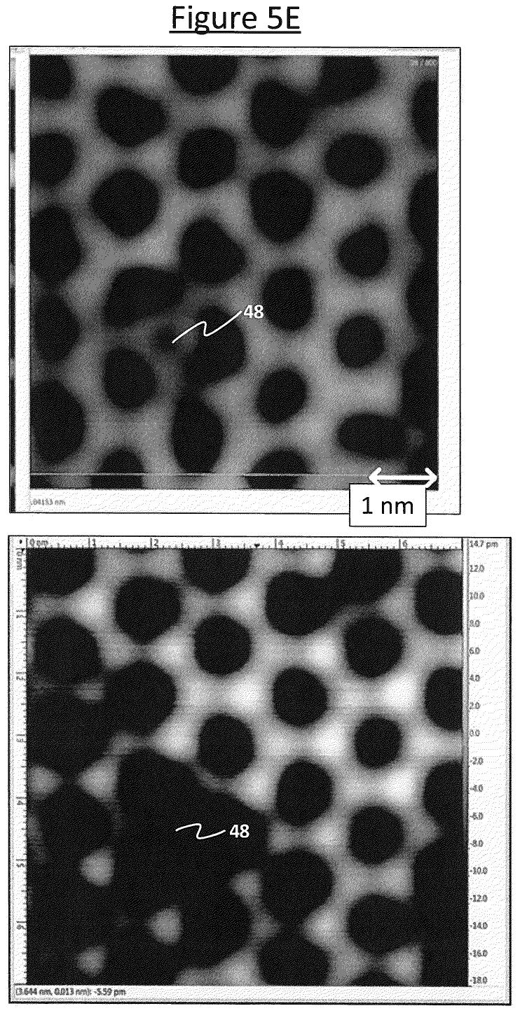

For instance, a different arrangement of Pb atoms may be formed that has the same periodicity as the underlying substrate, albeit with doubled lattice constant can be formed (a 2×2 reconstruction). The periodicity of the atoms can be seen from the low-energy electron diffraction pattern shown in FIG. 5A taken by the inventors, where 44 denotes the diffraction spots that coincide with the diffraction spots from the underlying substrate, and 42 indicates the additional diffraction spots at the midpoint between two spots 44. This lattice can also be observed in an STM image taken by the inventors shown in FIG. 5B, where region 46 indicates the substrate region, and 48 the region of the reconstructed lattice. FIG. 5C shows zoomed STM images of region 44 in FIG. 5B, probing the unoccupied and occupied states, respectively.

FIGS. 5D to 5E show a long-range honeycomb structure formed using the disclosed techniques. The long-range honeycomb structure has a lattice constant ^{˜}1.3 to 1.5 nm. The disclosed techniques may be used for example to form an atomic honeycomb, a Moiré super lattice, or a kagome structure. FIG. 5E also shows the presence of some defects 48 in the fabricated structure.

It will be appreciated that the above embodiments have been described by way of example only.

More generally, according to one aspect disclosed herein, there is provided a device comprising: a substrate comprising a III-V semiconductor having a crystalline surface; and a kagome lattice formed from atoms of an element with atomic number Z greater than or equal to 14, deposited on said surface of the semiconductor.

In embodiments the atomic number Z of said element may be greater than or equal to 32. In embodiments the atomic number of said element Z may be greater than or equal to 82.

In embodiments said element may be Pb.

In embodiments, the device may comprise additional Pb atoms formed along one or more edges between nodes of the kagome lattice.

In embodiments, a (111) face of the crystalline structure of the semiconductor may be presented at said surface.

In embodiments, the surface may be a III-V(111) B face of the semiconductor whereby a (111) face of the group V element terminates the crystalline structure of the semiconductor at said surface.

In embodiments, the III-V semiconductor may be or comprise one of: InAs, InSb, InP, GaAs, or GaSb.

In embodiments, the surface of the substrate may be substantially flat and devoid of oxides.

According to another aspect of the present disclosure, there is provided a method of operating the device of any embodiment disclosed herein, the method comprising: gating the device to control an atomic band structure of the kagome lattice

In embodiments the meth may comprise thereby tuning between different topological phases.

According to another aspect disclosed herein, there is provided a method of depositing an element onto a substrate so as to form a lattice structure, the method comprising: providing a substrate comprising at least a layer of a III-V semiconductor; treating the substrate to provide a cleaned, exposed surface of the semiconductor having a crystalline structure terminated at said surface; depositing a layer of the element on said surface, wherein the element has an atomic number Z greater than or equal to 14; and annealing the heavy element following said deposition so as to increase mobility of the element on said surface, wherein the heavy element interacts with the crystalline structure at the surface of the semiconductor during at least a period of said increased mobility in order to form said lattice structure.

In embodiments the lattice structure may be or comprise one of: a kagome lattice, a honeycomb, or a Moiré superlattice.

In embodiments said element may be Pb.

In embodiments, the providing of the substrate may comprise forming said layer by buffer growth.

In embodiments, said treating may comprise: passivating the semiconductor with an amorphous layer of the group V element, and annealing the surface to remove the amorphous layer.

In embodiments, the crystal structure of the semiconductor may terminate with a (III) face of the group V element at said surface.

In embodiments, said deposition of the heavy element may be performed using an electron beam evaporator.

In embodiments, the III-V semiconductor may be or comprise one of: InAs, InSb, InP, GaAs, or GaSb.

Other variants or use cases of the disclosed techniques may become apparent to the person skilled in the art once given the disclosure herein. The scope of the disclosure is not limited by the described embodiments but only by the accompanying claims.

1. A device comprising:
a substrate comprising a III-V semiconductor having a crystalline surface; and
a kagome lattice formed from atoms of an element with atomic number Z greater than or equal to 14, deposited on said surface of the semiconductor.

2. The device of claim 1, wherein said element is Pb.

3. The device of claim 2, comprising additional Pb atoms formed along one or more edges between nodes of the kagome lattice.

4. The device of claim 3, wherein a (111) face of the crystalline structure of the semiconductor is presented at said surface.

5. The device of claim 4, wherein the surface is a III-V(111) B face of the semiconductor whereby a (111) face of the group V element terminates the crystalline structure of the semiconductor at said surface.

6. The device of claim 1, wherein the III-V semiconductor comprises one of: InAs, InSb, InP, GaAs, or GaSb.

7. The device of claim 6, wherein the semiconductor is InAs.

8. The device of claim 1, wherein the surface of the substrate is substantially flat and devoid of oxides.

9. A method of depositing an element onto a substrate so as to form a lattice structure, the method comprising:
providing a substrate comprising at least a layer of a III-V semiconductor;
treating the substrate to provide a cleaned, exposed surface of the semiconductor having a crystalline structure terminated at said surface;
depositing a layer of the element on said surface, wherein the element has an atomic number Z greater than or equal to 14; and
annealing the element following said deposition so as to increase mobility of the element on said surface, wherein the element interacts with the crystalline structure at the surface of the semiconductor during at least a period of said increased mobility in order to form said lattice structure.

10. The method of claim 9, wherein the lattice structure comprises one of: a kagome lattice, a honeycomb, or a Moiré superlattice.

11. The method of claim 9, wherein said element is Pb.

12. The method of claim 9, wherein the providing of the substrate comprises forming said layer by buffer growth.

13. The method of any of claim 9, wherein said treating comprises:
passivating the semiconductor with an amorphous layer of the group V element, and
annealing the surface to remove the amorphous layer.

14. The method of any of claim 9, wherein the crystal structure of the semiconductor terminates with a (III) face of the group V element at said surface.

15. The method of claim 9, wherein the III-V semiconductor comprises one of: InAs, InSb, InP, GaAs, or GaSb.

16. The method of claim 10, wherein the lattice structure is a kagome lattice.

17. The method of claim 9, wherein said deposition of said element is performed using an electron beam evaporator.

18. The method of claim 15, wherein the semiconductor is InAs.

19. A method of operating the device of claim 1, the method comprising gating the device to control an atomic band structure of the kagome lattice.

20. The method of claim 19, comprising thereby tuning between different topological phases.
